(19) United States
(12) Patent Application Publication
(10) Pub. No.: US 2025/0275062 A1
(43) Pub. Date: Aug. 28, 2025

(54) PRINTED CIRCUIT BOARD

(71) Applicant: SAMSUNG ELECTRO-MECHANICS CO., LTD., Suwon-si (KR)

(72) Inventors: Sang Jong LEE, Suwon-si (KR); Dae Chul CHOI, Suwon-si (KR); Jung Ho SHIM, Suwon-si (KR)

(73) Assignee: SAMSUNG ELECTRO-MECHANICS CO., LTD., Suwon-si (KR)

(21) Appl. No.: 18/955,342

(22) Filed: Nov. 21, 2024

(30) Foreign Application Priority Data
Feb. 26, 2024 (KR) 10-2024-0027002

(51) Int. Cl. H05K 1/18; H01L 23/00; H01L 23/31; H01L 25/065; H05K 1/11; H05K 1/14; H05K 3/00; H05K 3/40

(52) U.S. Cl. CPC H05K 1/181; H01L 23/3107; H01L 25/065; H05K 1/113; H05K 1/144; H05K 1/185; H05K 3/0047; H05K 3/4038; H01L 24/16; H01L 2224/16227; H05K 2201/041; H05K 2201/049; H05K 2201/08; H05K 2201/10015; H05K 2201/10378; H05K 2201/10545; H05K 2203/1316

(57) ABSTRACT

The present disclosure relates to a printed circuit board including: a magnetic layer; a plurality of through-vias respectively penetrating through the magnetic layer; a plurality of first pads disposed on upper surfaces of the plurality of through-vias, respectively; a plurality of second pads disposed on lower surfaces of the plurality of through-vias, respectively; a first insulating layer covering at least portions of the plurality of first pads; a second insulating layer covering at least portions of the plurality of second pads. At least a portion of a side surface of the magnetic layer is substantially coplanar with at least a portion of one or more of a side surface of the first insulating layer and a side surface of the second insulating layer.

### CROSS-REFERENCE TO RELATED APPLICATION(S)

This application claims benefit of priority to Korean Patent Application No. 10-2024-0027002 filed on Feb. 26, 2024, in the Korean Intellectual Property Office, the disclosure of which is incorporated herein by reference in its entirety.

### TECHNICAL FIELD

The present disclosure relates to a printed circuit board, for example, a printed circuit board including a plurality of inductor array structures.

With an increase in demand for power efficiency, such as power consumption reduction of electronic devices, the frequency of power supply devices is becoming ever higher, and accordingly, the capacity of power inductors required is becoming ever lower. In addition, a Power Management Integrated Circuit (PMIC) used in general and server computers for voltage regulation may be subject to an output method of integrating multiple output voltages, thus increasing power efficiency, and as a result, the use of low-capacity inductors has increased even more. On the other hand, in the case of low-capacity inductors, since it is not easy to implement low capacities in existing chip shapes, inductance is mainly implemented in a pattern shape directly on the printed circuit board. However, since these pattern-shaped inductors do not use magnetic materials unlike chip-shaped inductors, they have relatively lower capacitance per unit volume, larger volume, and higher resistance, as compared to chip inductors.

### SUMMARY

An aspect of the present disclosure is to provide a printed circuit board that may reduce a size of an inductor, may arrange the required number of inductors and may also be easily mounted or embedded in other boards.

One of the various solutions provided through the present disclosure is to implement an inductor structure including a magnetic material, for example, a magnetic core array inductor (MCAI) structure using a printed circuit board.

For example, a printed circuit board according to an example embodiment may include: a magnetic layer; a plurality of through-vias respectively penetrating through the magnetic layer; a plurality of first pads disposed on upper surfaces of the plurality of through-vias, respectively; a plurality of second pads disposed on lower surfaces of the plurality of through-vias, respectively; a first insulating layer covering at least portions of the plurality of first pads; a second insulating layer covering at least portions of the plurality of second pads. At least a portion of a side surface of the magnetic layer may be substantially coplanar with at least a portion of one or more of a side surface of the first insulating layer and a side surface of the second insulating layer.

For example, a printed circuit board may include: a magnetic layer having a plurality of through-holes; a plurality of insulating films respectively disposed on wall surfaces of the plurality of through-holes; a plurality of metal pillars respectively disposed on the plurality of insulating films and disposed in at least portions of the plurality of through-holes; an insulating layer covering one or more of an upper surface and a lower surface of the magnetic layer; and a plurality of metal patterns each of which is at least partially embedded in the insulating layer and is respectively connected to one or more of upper surfaces and lower surfaces of the plurality of metal pillars. At least a portion of a lower surface of the magnetic layer may be substantially coplanar with at least a portion of a lower surface of at least one of the plurality of metal pillars.

One of the various effects of the present disclosure is to provide a printed circuit board that may reduce a size of an inductor, may arrange the required number of inductors, and may also be easily mounted or embedded in other boards.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a block diagram schematically illustrating an example of an electronic device system;

FIG. 2 is a perspective view schematically illustrating an example of an electronic device;

FIG. 3 is a cross-sectional view schematically illustrating an example of a printed circuit board;

FIGS. 4A to 4I are process cross-sectional views schematically illustrating an example of manufacturing the printed circuit board of FIG. 3;

FIG. 5 is a cross-sectional view schematically illustrating another example of a printed circuit board;

FIGS. 6A to 6J are process-sectional views schematically illustrating an example of manufacturing the printed circuit board of FIG. 5;

FIG. 7 is a cross-sectional view schematically illustrating another example of a printed circuit board;

FIGS. 8A to 8I are process-sectional views schematically illustrating an example of manufacturing the printed circuit board of FIG. 7;

FIGS. 9 to 11 are cross-sectional views schematically illustrating modified examples of the printed circuit board of FIGS. 3, 5 and 7, respectively;

FIGS. 12 to 14 are cross-sectional views schematically illustrating other modified examples of the printed circuit board of FIGS. 3, 5 and 7, respectively;

FIGS. 15 to 17 are cross-sectional views schematically illustrating other modified examples of the printed circuit board of FIGS. 3, 5, and 7, respectively; and

FIG. 18 is a cross-sectional view schematically illustrating another example of a printed circuit board.

### DETAILED DESCRIPTION

Hereinafter, the present disclosure will be described with reference to the accompanying drawings. In the drawings, the shape and size of the elements may be exaggerated or reduced for clearer description.

### Electronic Device

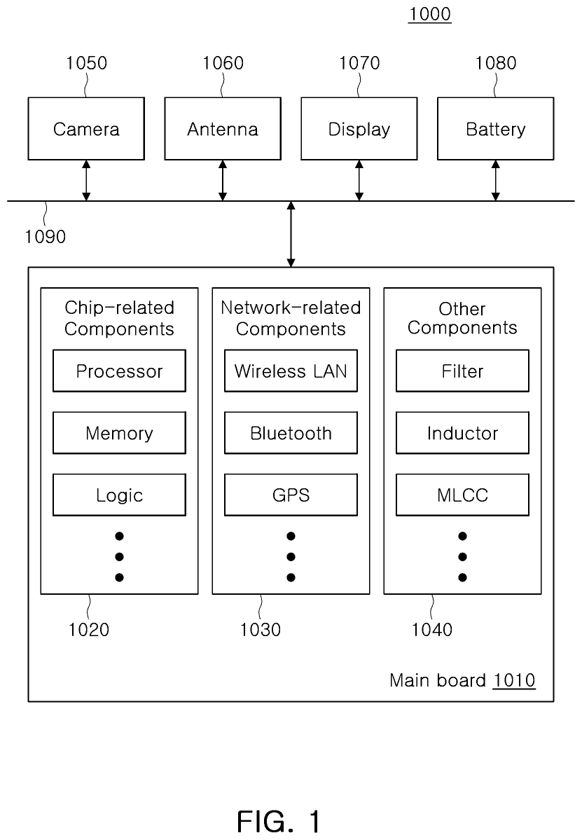

FIG. 1 is a block diagram schematically illustrating an example of an electronic device system.

Referring to FIG. 1, an electronic device 1000 accommodates a main board 1010 therein. Chip-related components 1020, network-related components 1030, and other components 1040, and the like, are physically and/or electrically connected to the main board 1010. These components are also coupled to other electronic components to be described below to form various signal lines 1090.

The chip-related components 1020 may include a memory chip such as a volatile memory (e.g., a DRAM), a non-volatile memory (e.g., a ROM), a flash memory, or the like; an application processor chip such as a central processor (e.g., a CPU), a graphics processor (e.g., a GPU), a digital signal processor, a cryptographic processor, a microprocessor, a microcontroller, or the like; and a logic chip such as an analog-to-digital (ADC) converter, an application-specific IC (ASIC), or the like. However, the chip-related components 1020 are not limited thereto, and may also include other types of chip-related electronic components. Furthermore, the chip-related components 1020 may be coupled to each other. The chip-related component 1020 may have the form of a package including the above-described chip or electronic component.

The network-related components 1030 may include wireless fidelity (Wi-Fi) (such as IEEE 802.11 family), worldwide interoperability for microwave access (WiMAX) (such as IEEE 802.16 family), IEEE 802.20, long term evolution (LTE), evolution data only (Ev-DO), HSPA+, HSDPA+, HSUPA+, EDGE, GSM, GPS, GPRS, CDMA, TDMA, DECT, Bluetooth, 3G, 4G, and 5G protocols, and any other wireless and wired standards or protocols specified thereafter. However, the network-related components 1030 are not limited thereto, and may also include any of a number of other wireless or wired standards or protocols. Furthermore, the network-related components 1030 may be coupled to the chip-related components 1020.

Other components 1040 may include a high frequency inductor, a ferrite inductor, a power inductor, ferrite beads, a low temperature co-firing ceramic (LTCC), an electromagnetic interference (EMI) filter, a multilayer ceramic capacitor (MLCC), or the like. However, other components are not limited thereto, and may also include passive components in the form of chip components used for various other purposes. In addition, other components 1040 may be coupled to each other, together with the chip-related components 1020 and/or the network-related components 1030.

Depending on a type of electronic device 1000, the electronic device 1000 may include other electronic components that may or may not be physically and/or electrically connected to main board 1010. These other electronic components may include, for example, a camera module 1050, an antenna module 1060, a display 1070, and a battery 1080. However, these other electronic components are not limited thereto, but may also include an audio codec, a video codec, a power amplifier, a compass, an accelerometer, a gyroscope, a speaker, a mass storage device (e.g., a hard disk drive), a compact disk (CD), a digital versatile disk (DVD), or the like. In addition thereto, other electronic components used for various purposes depending on a type of electronic device 1000 may be included.

The electronic device 1000 may be a smartphone, a personal digital assistant, a digital video camera, a digital still camera, a network system, a computer, a monitor, a tablet PC, a laptop PC, a netbook PC, a television, a video game machine, a smartwatch, an automotive component. However, the electronic device 1000 is not limited thereto, and may be any other electronic device that processes data in addition thereto.

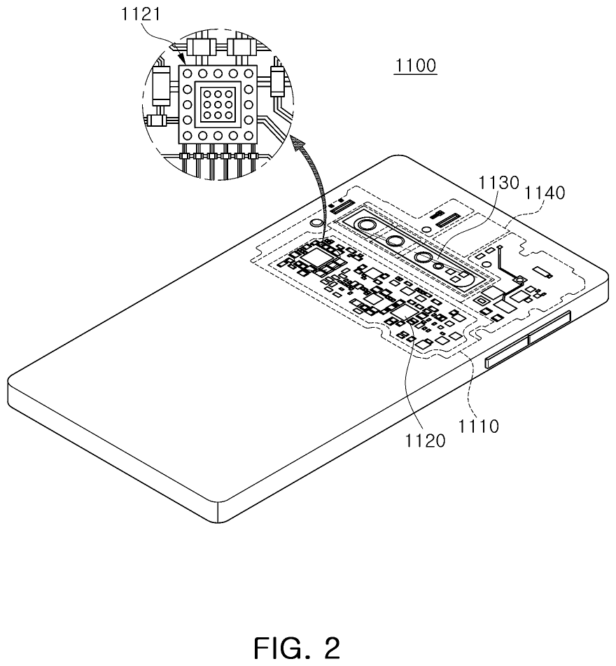

FIG. 2 is a perspective view schematically illustrating an example of an electronic device.

Referring to FIG. 2, an electronic device may be, for example, a smartphone 1100. A mother board 1110 may be accommodated in the smartphone 1100, and various components 1120 may be physically and/or electrically connected to the mother board 1110. Furthermore, other components that may or may not be physically and/or electrically connected to the mother board 1110, such as a camera module 1130 and/or a speaker 1140, may be accommodated in the smartphone 1100. Some of the components 1120 may be the chip-related components described above, for example, the component package 1121, but the present disclosure is not limited thereto. The component package 1121 may have the form of a printed circuit board in which an electronic component including an active component and/or a passive component is mounted on a surface. Alternatively, the component package 1121 may have the form of a printed circuit board in which an active component and/or a passive component are embedded. On the other hand, the electronic device is not necessarily limited to the smartphone 1100, and may be other electronic devices as described above.

### Printed Circuit Board

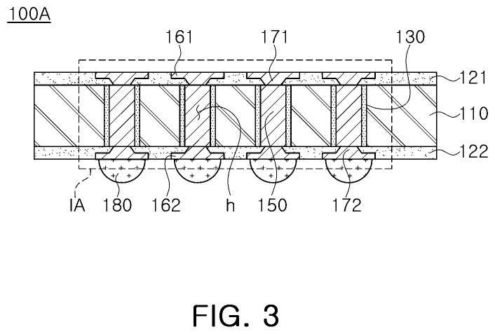

FIG. 3 is a cross-sectional view schematically illustrating an example of a printed circuit board.

Referring to FIG. 3, a printed circuit board 100A according to an example embodiment may include a magnetic layer 110, a plurality of through-vias 150 respectively penetrating through the magnetic layer 100, a plurality of first pads 161 disposed on an upper surface of each of the plurality of through-vias 150, a plurality of second pads 162 disposed on a lower surface of each of the plurality of through-vias 150, a first insulating layer 121 covering at least portions of each of the plurality of first pads 161, a second insulating layer 122 covering at least portions of each of the plurality of second pads 162, a plurality of first connection vias 171 respectively penetrating through the first insulating layer 121 and connecting each of the plurality of first pads 161 to upper surfaces of each of the plurality of through-vias 150, a: plurality of second connection vias 172 respectively penetrating through the second insulating layer 122 and connecting each of the plurality of second pads 162 to lower surfaces of each of the plurality of through-vias 150, and a plurality of insulating layers 130 disposed between each of the plurality of through-vias 150 and the magnetic layer 110 and surrounding side surfaces of each of the plurality of through-vias 150.

For example, a printed circuit board 100A according to an example embodiment may include a magnetic core array inductor (MCAI) structure, and more specifically, the printed circuit board 100A may include an inductor array IA including a magnetic layer 110, first and second insulating layers 121 and 122, a plurality of insulating films 130, a plurality of through-vias 150, a plurality of first and second pads 161 and 162, and a plurality of first and second connecting vias 171 and 172. Each inductor included in the inductor array IA may include a through-via 150 and first and second pads 161 and 162 connected to an upper portion and a lower portion of the through-via 150 through the first and second connection vias 171 and 172. Each of these inductors may form one or more coils. For example, metal patterns connected to the plurality of first pads 161 and/or the plurality of second pads 162 may include coil patterns having various shapes. Alternatively, each of the inductors may include two or more of the through-via 150, the first and second connection vias 171 and 172, and the first and second pads 161 and 162, which may be electrically connected to each other to form one or more coils. Each of these inductors may be electrically connected to each other. For example, at least two of the plurality of first pads 161 may be electrically connected to each other in various forms through metal patterns, or the like, and/or at least two of the plurality of second pads 162 may be electrically connected to each in various forms through metal patterns, or the like. In this manner, two or more inductors may be electrically connected to each other to form one or more coils.

Meanwhile, at least a portion of a side surface of the magnetic layer 110 may be substantially coplanar with at least portions of side surfaces of each of the first and second insulating layers 121 and 122. For example, the magnetic layer 110 may be formed in the form of a stack body by stacking, compressing and sintering a plurality of magnetic films as in a process described below. Additionally, after forming a through-hole h in the magnetic layer 110 in the form of a stack body, at least a portion of the through-hole h may be filled with a metal, thus forming a plurality of through-vias 150, for example, a plurality of metal pillars. Additionally, the first and second insulating layers 121 and 122 may be further stacked on the upper surface and the lower surface of the magnetic layer 110 in the form of the stack body, respectively, and a plurality of first and second pads 161 and 162 and a plurality of first and second connection vias 171 and 172, for example, a plurality of metal patterns, may be formed on the first and second insulating layers 121 and 122. Then, the printed circuit board 100A may be formed in the form of a unit board having a required size through a cutting process, or the like. Accordingly, the side surface of the magnetic layer 110, more specifically, an external surface of the magnetic layer 110, may be exposed externally. Since the printed circuit board 100A having the structure basically includes the magnetic layer 110, the size of the inductor may be reduced. Additionally, since the inductor array structure may be implemented by the plurality of through-vias 150, the plurality of first and second pads 161 and 162, and the like, a plurality of inductors may be easily arranged as needed. Additionally, the capacity of the inductor may be easily adjusted by adjusting a size, a material, or the like, of the magnetic layer 110 and a size of the through-hole h formed therein. Additionally, a first electrical connection metal 180, such as a solder ball, may be connected to each of the plurality of second pads 162 to implement a Ball Grid structure, so that the printed circuit board Array (BGA) 100A may be easily mounted on other boards. Additionally, space efficiency may increase as compared to simply forming a pattern inductor on a board, and the design freedom of another board on which the MCAI structure is mounted may be increased.

Meanwhile, each of the plurality of insulating films 130 may include an inorganic insulating material. For example, each of the plurality of insulating films 130 may include an inorganic oxide film. The inorganic oxide film may include, for example, one or more of Al₂O₃, TiO₂, ZnO, ZnO₂, ZrO₂, SnO, SnO₂, HfO₂ and SiO₂, but the present disclosure is not limited thereto. The plurality of insulating films 130 may be formed in a deposition process using such inorganic insulating materials, and therefore may be formed with a thin thickness. For example, in a cross-section, based on a direction, perpendicular to side surfaces of each of the plurality of through-vias 150, widths of each of the plurality of insulating films 130 may be 2 μm or less, for example, approximately 1 μm to 2 μm, but the present disclosure is not limited thereto. In this manner, when the plurality of insulating films 130 are formed thinly, a width of the magnetic layer 110 may be sufficiently secured, thereby easily adjusting the capacity of the inductor.

Meanwhile, the upper surface of the magnetic layer 110, the upper surfaces of each of the plurality of insulating films 130, and the upper surfaces of each of the plurality of through-vias 150 may be substantially coplanar with each other. Additionally, the lower surface of the magnetic layer 110, the lower surfaces of each of the plurality of insulating films 130, and the lower surfaces of each of the plurality of through-vias 150 may be substantially coplanar with each other. For example, as in a process described below, after forming the plurality of insulating films 130 and the plurality of through-vias 150 on the magnetic layer 110, a planarization process such as polishing may be performed, and thus the upper surfaces and the lower surfaces thereof may be substantially flat. Accordingly, the first and second insulating layers 121 and 122 covering the upper surfaces and the lower surfaces thereof may also have better planarity. Accordingly, the plurality of first and second pads 161 and 162 formed on the first and second insulating layers 121 and 122 may be formed more easily.

Meanwhile, the first and second insulating layers 121 and 122 may include substantially the same insulating material. For example, the first and second insulating layers 121 and 122 may be substantially the same insulating layers. Accordingly, thicknesses of the first and second insulating layers 121 and 122 may be substantially the same as each other. Accordingly, the first and second insulating layers 121 and 122 may have a substantially vertically symmetrical structure centered on the magnetic layer 110. Accordingly, the first and second insulating layers 121 and 122 may be more advantageous for warpage control, or the like.

Meanwhile, if necessary, a separate third insulating layer may cover at least portions of the side surfaces of the magnetic layer 110 and the first and second insulating layers 121 and 122. For example, if necessary, the magnetic layer 110 may not be exposed externally by the first and second insulating layers 121 and 122 and an additional third insulating layer.

Hereinafter, components of the printed circuit board 100A according to an example embodiment will be described in more detail with reference to the drawings.

The magnetic layer 110 may include a magnetic material. The magnetic material may include, for example, a ferrite-based material and a permalloy-based material. For example, the magnetic layer 110 may include Ni-based ferrite, Ni—Zn-based ferrite, Ni—Zn—Cu-based ferrite, Fe—Si—Al (Sendust), Ni—Mo—Fe (MPP: Molypermalloy Powder Core), and Ni—Fe (High Flux Core), but the present disclosure is not limited thereto, and the magnetic layer 110 may include other known ferrite-based materials or permalloy-based materials. Additionally, various types of magnetic materials including other magnetic powders and/or magnetic particles may be used as the magnetic layer 110. The magnetic layer 110 may be hardened in the form of a magnetic film or a magnetic sheet and may thus be disposed as a core layer. The magnetic layer 110 may have a plurality of through-holes h, and the plurality of through-holes h may be spaced apart from each other and may penetrate between the upper and lower surfaces of the magnetic layer 110.

Each of the first and second insulating layers 121 and 122 may include an organic insulating material. For example, the first and second insulating layers 121 and 122 may each include substantially the same organic insulating material. The organic insulating material may include a thermosetting resin such as an epoxy resin, a thermoplastic resin such as a polyimide, or an inorganic filler, an organic filler, and/or glass fiber (Glass Fiber, Glass Cloth or Glass Fabric) along with the resin. For example, the organic insulating material may be Prepreg (PPG), an Ajinomoto Build-up Film (ABF), Photoimageable Dielectric (PID), Solder Resist (SR), or the like, but the present disclosure is not limited thereto. If necessary, each of the first and second insulating layers 121 and 122 may be formed of a plurality of layers, in which case the first and second insulating layers 121 and 122 may have substantially the same number of layers.

Each of the plurality of insulating films 130 may include an inorganic insulating material. For example, each of the plurality of insulating films 130 may include an inorganic oxide film. The inorganic oxide film may include, for example, one or more of Al₂O₃, TiO₂, ZnO, ZnO₂, ZrO₂, SnO, SnO₂, HfO₂ and SiO₂, but the present disclosure is not limited thereto. The plurality of insulating films 130 may be formed in a deposition process using the inorganic insulating material, and may thus be formed with a thin thickness. For example, in a cross-section, based on a direction perpendicular to the side surfaces of each of the plurality of through-vias 150, widths of each of the plurality of insulating films 130 may be 2 μm or less, for example, approximately 1 μm to 2 μm, but the present disclosure is not limited thereto. Each of the plurality of insulating films 130 may be disposed to have the predetermined thickness described above on wall surfaces of each of the plurality of through-holes h with.

Each of the plurality of through-vias 150 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. Each of the plurality of through-vias 150 may include a plurality of metal pillars filling at least portions of each of the plurality of through-holes h. Each of the plurality of metal pillars may include a seed metal layer disposed on the insulating film 130 with a predetermined thickness and a plating metal layer disposed on the seed metal layer to substantially fill the through-holes h. The seed metal layer may be formed in electroless plating (or chemical copper), and, if necessary, the seed metal layer may be formed in a sputtering process. Alternatively, the seed metal layer may be formed using both the electroless plating and the sputtering process. The plating metal layer may be formed in electrolytic plating (or electrolytic copper). By the planarization process such as the polishing described below, the seed metal layer may be disposed on a side surface of the plating metal layer, but may not be disposed on an upper surface and a lower surface thereof. Additionally, the upper surfaces and the lower surfaces of the seed metal layer and the plating metal layer may substantially coplanar with each other. For example, the seed metal layer may be disposed in a form of entirely surrounding the side surface of the plating metal layer with a predetermined thin thickness, and the plating metal layer may fill a space formed by the seed metal. Each of the plurality of through-vias 150 may be included as some components of each inductor included in the inductor array IA.

Each of the plurality of first and second pads 161 and 162 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. Each of the plurality of first and second pads 161 and 162 may be included as portions of a plurality of metal patterns formed on the first and second insulating layers 121 and 122, respectively. Each of the plurality of metal patterns may perform various functions according to the design. For example, the plurality of metal patterns may include a signal pattern, a power pattern, a ground pattern, and a coil pattern. Each of these patterns may have various shapes, such as a line, a plane, a pad, or the like. At least two of the plurality of first pads 161 may be electrically connected to each other through another metal pattern or the like. At least two of the plurality of second pads 162 may be electrically connected to each other through another metal pattern, or the like. Each of the plurality of first and second pads 161 and 162 may include a seed metal layer and a plating metal layer. The seed metal layer may be formed in electroless plating (or chemical copper), and, if necessary, the seed metal layer may be formed in a sputtering process. Alternatively, the seed metal layer may be formed using both the electroless plating and the sputtering process. The plating metal layer may be formed in electrolytic plating (or electroplating). The plurality of first and second pads 161 and 162 may be embedded and disposed in the first and second insulating layers 121 and 122, respectively, but the present disclosure is not limited thereto, and, if necessary, the plurality of first and second pads 161 and 162 may be disposed by protruding on the first and second insulating layers 121 and 122. Each of the plurality of first and second pads 161 and 162 may be included as some components of each inductor included in the inductor array IA.

Each of the plurality of first and second connection vias 171 and 172 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the disclosure is not limited thereto. Each of the plurality of first and second connection vias 171 and 172 may be included as another portion of the plurality of metal patterns described above. Each of the plurality of first connection vias 171 may be formed integrally with each of the plurality of first pads 161. Each of the plurality of second connection vias 172 may be formed integrally with each of the plurality of second pads 162. Each of the plurality of first and second connection vias 171 and 172 may include the seed metal layer and the plating metal layer described above, which are included in each of the plurality of first and second pads 161 and 162. Each of the plurality of first and second connection vias 171 and 172 may include a filled VIA filling a via hole, but may also include a conformal VIA disposed along a wall surface of the via hole. The plurality of first and second connection vias 171 and 172 may have shapes tapered in opposite directions in cross section. Each of the plurality of first and second connection vias 171 and 172 may be included as some components of each inductor included in the inductor array IA.

The plurality of first electrical connection metal portions 180 may connect the printed circuit board 100A to another board, or the like. The plurality of first electrical connection metal portions 180 may be connected to the plurality of second pads 162, respectively. If necessary, the plurality of first electrical connection metal portions 180 may be respectively connected to the plurality of second pads 162 through the plurality of underbump metal portions. The plurality of first electrical connection metal portions 180 may be formed of a conductive material, for example, solder, or the like, but this is only an example and the material is not limited thereto. Each of the plurality of first electrical connection metal portions 180 may be a land, a ball, a pin, or the like. Each of the plurality of first electrical connection metal portions 180 may be formed as a multilayer or a single layer structure. In the case in which the plurality of first electrical connection metal portions 180 are formed as the multilayer, the plurality of first electrical connection metal portions 180 may include a copper pillar and solder formed on the copper pillar, and in the case in which the plurality of first electrical connection metal portions 180 are formed as the single layer, the plurality of first electrical connection metal portions 180 may include tin-silver solder or copper, but the material included therein are not limited thereto.

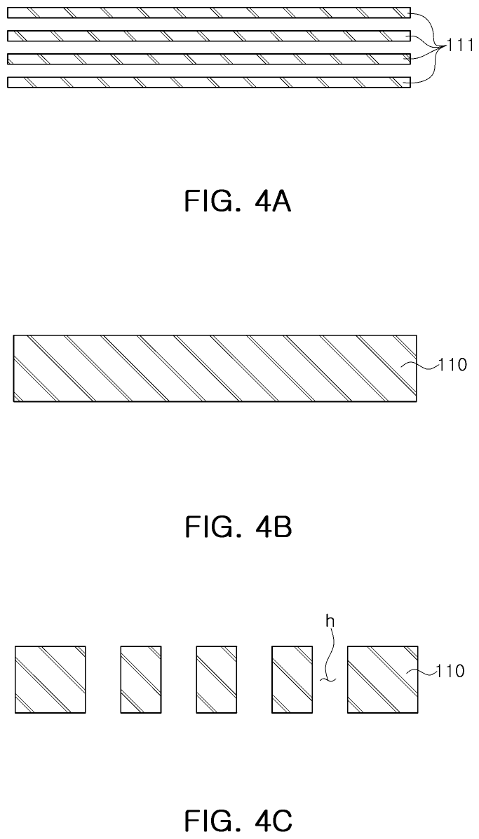

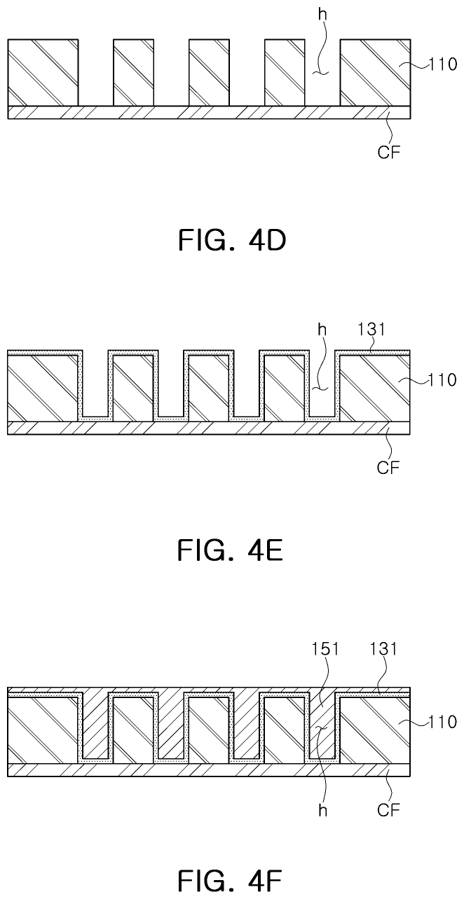

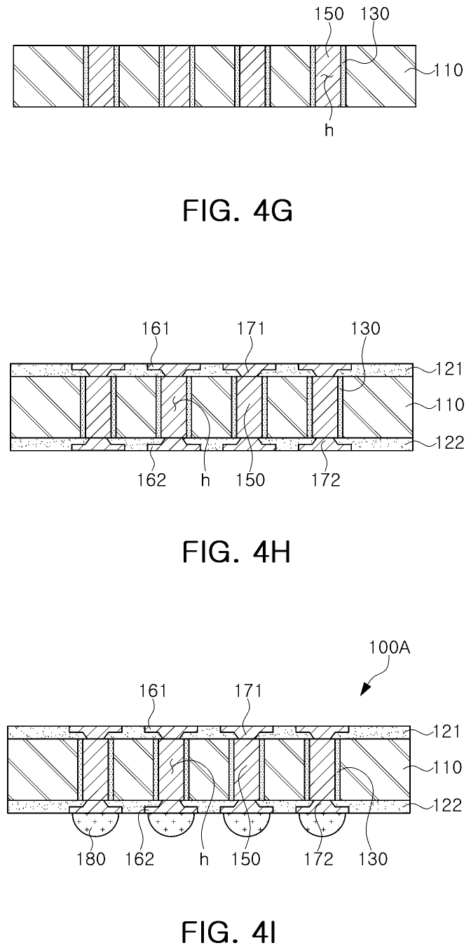

FIGS. 4A to 4I are schematic process cross-sectional views illustrating an example of manufacturing a printed circuit board of FIG. 3.

Referring to FIG. 4A, a plurality of magnetic films 111 may be prepared. The plurality of magnetic films 111 may include substantially the same material, for example, the magnetic material described above.

Referring to FIG. 4B, a plurality of magnetic films 111 may be stacked and compressed and then sintered. Therethrough, a magnetic layer 110 may be formed.

Referring to FIG. 4C, a plurality of through-holes h may be formed in the magnetic layer 110. The plurality of through-holes h may be formed using a CNC drill, or the like. Referring to FIG. 4D, a carrier film CF may be attached to a lower side of the magnetic layer 110. A material of the carrier film CF may not be particularly limited.

Referring to FIG. 4E, a passivation layer 131 may be formed on the magnetic layer 110. For example, by utilizing a non-metallic insulator as a material, a thin passivation layer 131 may be formed using a deposition process such as Chemical Vapor Deposition (CVD) or Atomic Layer Deposition (ALD). The passivation layer 131 may cover the upper surface of the magnetic layer 110, the wall surfaces of each of the plurality of through-holes h, and an exposed upper surface of the carrier film CF.

Referring to FIG. 4F, a metal layer 151 may be formed on the passivation layer 131. The metal layer 151 may fill the remaining space of each of the plurality of through-holes h. The metal layer 151 may be formed in a plating process. For example, a seed metal layer may be formed in electroless plating, and a plating metal layer may be formed in electrolytic plating. If necessary, a sputtering process may be used to form the seed metal layer, or both the electroless plating and the sputtering process may be used to form the seed metal layer.

Referring to FIG. 4G, the carrier film CF may be removed, and the upper surface and the lower surface of the magnetic layer 110 may be planarized. In this process, portions of each of the magnetic layer 110, the passivation layer 131 and the metal layer 151 may be removed. Accordingly, planarized upper and lower surfaces may be provided. Additionally, the plurality of through-vias 150 and the plurality of insulating films 130 may be formed. In the planarization process, for example, a polishing process such as Chemical Mechanical Polishing (CMP) may be used.

Referring to FIG. 4H, first and second insulating layers 121 and 122 may be formed on the upper surface and the lower surface of the magnetic layer 110 in a stacking process or a coating process, respectively. Additionally, pattern hole processing and/or via hole processing may be performed on the first and second insulating layers 121 and 122, and then a plating process may be performed to form a plurality of metal patterns including the plurality of first and second pads 161 and 162 and the plurality of first and second connection vias 171 and 172.

Referring to FIG. 4I, the plurality of first electrical connection metal portions 180 may be connected to the plurality of second pads 162, respectively. Each of the plurality of first electrical connection metal portions 180 may be formed in a solder ball attachment and reflow process. If necessary, a cutting process may be performed. The printed circuit board 100A in the form of the unit board described above may be formed in the cutting process.

Other descriptions may be substantially the same as those described for the above-described printed circuit board 100A, and duplicate descriptions thereof will be omitted.

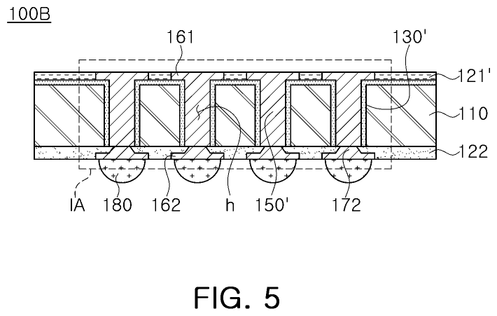

FIG. 5 is a cross-sectional view schematically illustrating another example of a printed circuit board.

Referring to FIG. 5, a printed circuit board 100B according to another example embodiment may be configured so that each of a plurality of insulating layers 130′ may extend onto an upper surface of the magnetic layer 110, and at least portions of extended portions of each of the insulating layers 130′ may be disposed between a first insulating layer 121′ and the magnetic layer 110, in the printed circuit board 100A according to the above-described example embodiment. A plurality of insulating layers 130′ may be connected to each other in the extended portions, and may be entirely connected, for example, to form one passivation layer accordingly. Additionally, an upper surface of each of a plurality of through-vias 150′ may protrude from an upper surface of the magnetic layer 110, and a plurality of first pads 161 may be directly connected to each of a plurality of through-vias 150. Additionally, the first and second insulating layers 121′ and 122 may include different insulating materials, and a thickness of the second insulating layer 122 may be thicker than a thickness of the first insulating layer 121′. For example, the printed circuit board 100B according to another example embodiment may have relatively asymmetric structure as compared to the structure of the printed circuit board 100A according to the above-described example embodiment. Meanwhile, the printed circuit board 100B according to another example embodiment may include an MCAI structure, and more specifically, the printed circuit board 100B may include an inductor array IA including the magnetic layer 110, the plurality of first and second insulating layers 121′ and 122, the plurality of insulating layers 130′, the plurality of through-vias 150′, a plurality of second pads 161 and 162, and a plurality of second connection vias 172. Meanwhile, if necessary, the first insulating layer 121′ may extend to cover at least portions of side surfaces of each of the magnetic layer 110 and the second insulating layer 122. Alternatively, if necessary, a separate third insulating layer may cover at least portions of side surfaces of each of the magnetic layer 110 and the first and second insulating layers 121 and 122.

Other descriptions may be substantially the same as those described in the printed circuit board 100A according to an example embodiment, and duplicate descriptions thereof will be omitted.

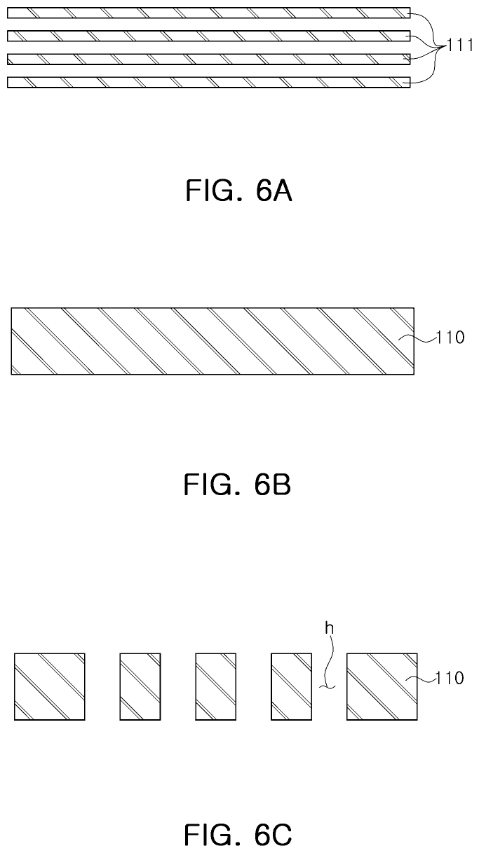

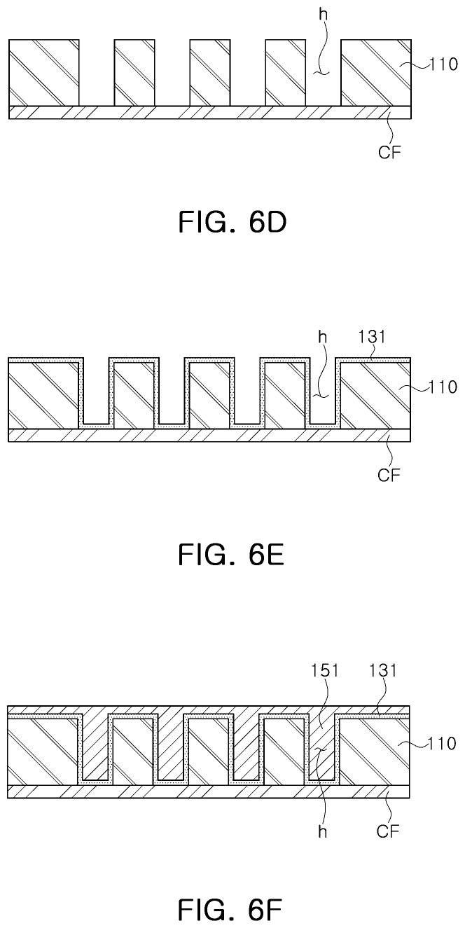

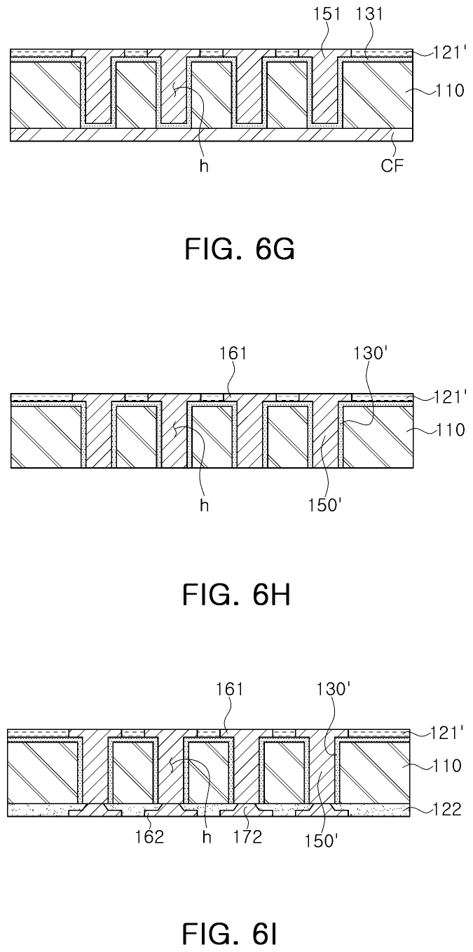

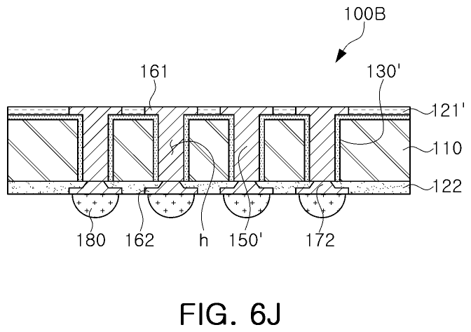

FIGS. 6A to 6J are process-sectional views schematically illustrating an example of manufacturing the printed circuit board of FIG. 5.

Referring to FIGS. 6A to 6F, the substantially same process as described in FIGS. 4A to 4F may be performed.

Referring to FIG. 6G, a portion of the metal layer 151 may be removed by etching or the like. For example, an upper region of the metal layer 151 may be patterned. Additionally, the first insulating layer 121′ may be formed in the region from which the metal layer 151 is removed, in a coating process or the like.

Referring to FIG. 6H, the carrier film CF may be removed, and a lower surface of the magnetic layer 110 may be planarized. In this process, portions of each of the magnetic layer 110, the passivation layer 131 and the metal layer 151 may be removed. Accordingly, a flat lower surface may be provided. Further, a plurality of through-vias 150′, a plurality of insulating layers 130′, and a plurality of upper metal patterns may be formed. The plurality of upper metal patterns may include a plurality of first pads 161. As the planarization process, for example, a polishing process such as CMP may be used.

Referring to FIG. 6I, a second insulating layer 122 may be formed on a lower surface of the magnetic layer 110 in a stacking process or a coating process. Additionally, pattern hole processing and/or via hole processing may be performed on the second insulating layer 122, and then, a plating process may be performed thereon, thus forming a plurality of lower metal patterns including a plurality of second pads 162 and a plurality of second connection vias 172.

Referring to FIG. 6J, a plurality of first electrical connection metal portions 180 may be connected to the plurality of second pads 162, respectively. A plurality of first electrical connection metal portions 180 may be formed in solder ball attachment and a reflow process, respectively. If necessary, a cutting process may be performed. The printed circuit board 100B in the form of the unit board described above may be formed in the cutting process.

Additionally, other descriptions may be substantially the same as those described in the above-described printed circuit boards 100A and 100B and the above-described manufacturing example of the printed circuit board 100A, and duplicate descriptions thereof will be omitted.

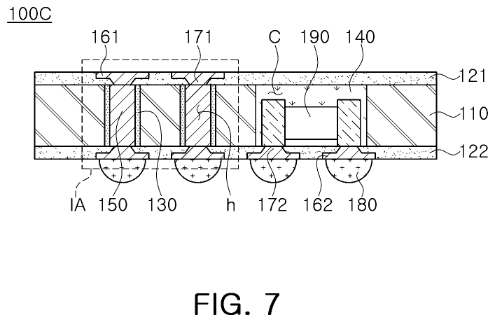

FIG. 7 is a cross-sectional view schematically illustrating another example embodiment of a printed circuit board.

Referring to FIG. 7, a printed circuit board 100C according to another example embodiment may be configured so that a magnetic layer 110 may have a cavity C, and a first electronic component 190 may be disposed in the cavity C, and an encapsulant 140 may cover at least a portion of the first electronic component 190 and fill at least a portion of the cavity C, in the printed circuit board 100A according to the above-described example embodiment. The cavity C may be a through-cavity, but the present disclosure is not limited thereto and may also be a blind cavity. The first electronic component 190 may include a chip type manual component such as an MLCC, or the like, but the present disclosure is not limited thereto, and the first electronic component 190 may include an integrated circuit chip such as integrated passive devices (IPD). The first electronic component 190 may be connected to at least one of a plurality of second pads 162 through at least one of a plurality of second connection vias 172. If necessary, the first electronic component 190 may be electrically connected to an inductor array IA through a plurality of metal patterns. The encapsulant 140 may include a known insulating material such as an epoxy resin. For example, the printed circuit board 100C according to another example embodiment may have an MCAI structure including the inductor array IA, and may have a structure of a substrate in which components are embedded simultaneously. Accordingly, more various functions may be provided, and an electrical path may be minimized. Meanwhile, if necessary, the inductor array IA in the printed circuit board 100B according to another example embodiment may be applied to the printed circuit board 100C according to another example embodiment.

Other descriptions may be substantially the same as those described in the printed circuit board 100A according to an example embodiment, the printed circuit board 100B according to another example embodiment, and the like, and duplicate descriptions thereof will be omitted.

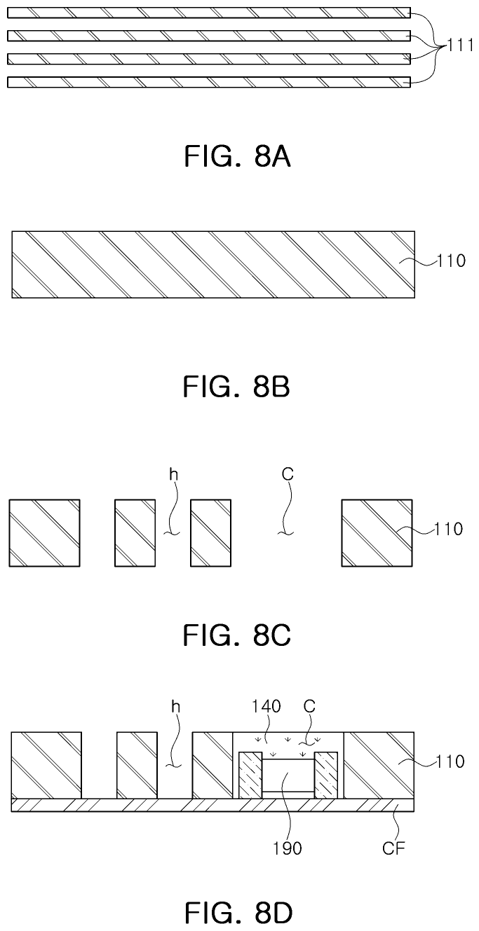

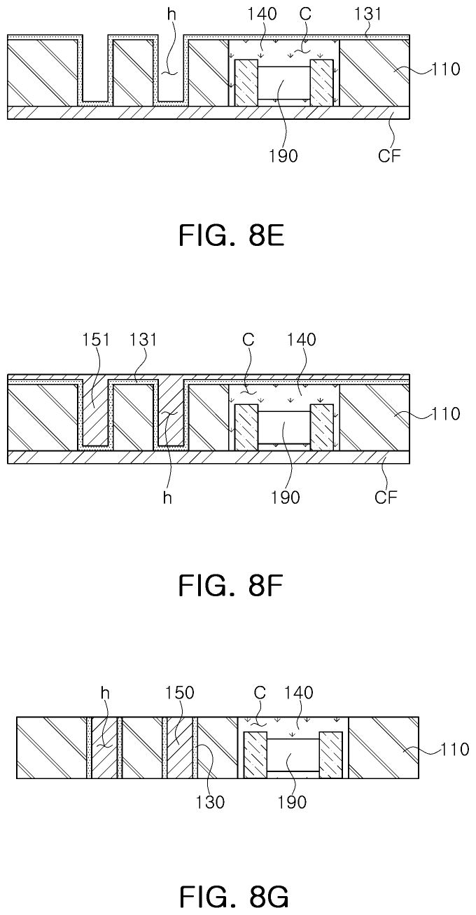

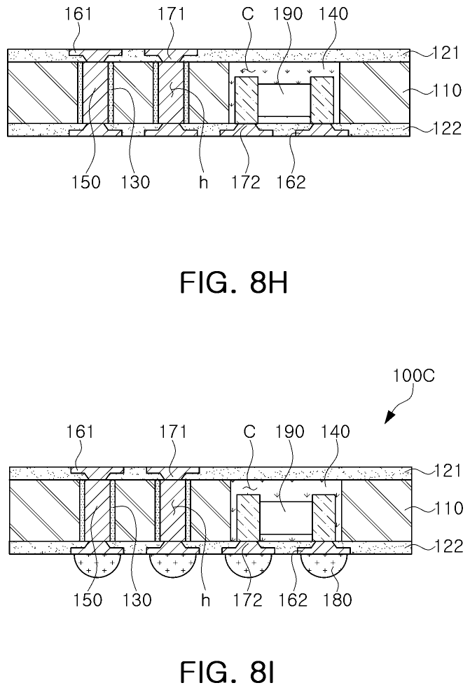

FIGS. 8A to 8I are process cross-sectional views schematically illustrating an example of manufacturing the printed circuit board of FIG. 7.

Referring to FIGS. 8A 8B, the process substantially the same as that described in FIGS. 4A to 4B described above may be performed.

Referring to FIG. 8C, a plurality of through-holes h and a cavity C may be formed in the magnetic layer 110. The plurality of through-holes h and the cavity C may be formed using a CNC drill, or the like.

Referring to FIG. 8D, the carrier film CF may be attached to a lower side of the magnetic layer 110. A material of the carrier film CF may not be particularly limited. Then, the first electronic component 190 may be disposed in the cavity C and may be sutured with an encapsulant 140.

Referring to FIG. 8E, a passivation layer 131 may be formed on the magnetic layer 110 and the encapsulant 140. For example, by utilizing a non-metallic insulator as a material, a thin passivation layer 131 may be formed using a deposition process such as CVD or ALD. The passivation layer 131 may cover an upper surface of the magnetic layer 110, an upper surface of the encapsulant 140, wall surfaces of each of the plurality of through-holes h, and an exposed upper surface of the carrier film CF.

Referring to FIG. 8F, a metal layer 151 may be formed on the passivation layer 131. The metal layer 151 may fill the remaining space of each of the plurality of through-holes h. The metal layer 151 may be formed in a plating process. For example, a seed metal layer may be formed in electroless plating, and a plating metal layer may be formed in electrolytic plating. If necessary, a sputtering process may be used to form the seed metal layer, or both the electroless plating and the sputtering processes may be used to form the seed metal layer.

Referring to FIG. 8G, the carrier film CF may be removed, and the upper surface and the lower surface of the magnetic layer 110 may be planarized. In this process, portions of each of the magnetic layer 110, the passivation layer 131 and the metal layer 151 may be removed. Accordingly, a flat upper surface and a flat lower surface may be provided. Additionally, a plurality of through-vias 150 and a plurality of insulating films 130 may be formed. As the planarization process, for example, a polishing process such as CMP may be used.

Referring to FIG. 8H, first and second insulating layers 121 and 122 may be formed on an upper surface and a lower surface of the magnetic layer 110 by a stacking process or a coating process, respectively. Additionally, pattern hole processing and/or via hole processing may be performed on the first and second insulating layers 121 and 122, and then a plating process may be performed thereon, thus forming a plurality of metal patterns including a plurality of first and second pads 161 and 162 and a plurality of first and second connection vias 171 and 172.

Referring to FIG. 8I, the plurality of first electrical connection metal portions 180 may be connected to the plurality of second pads 162, respectively. The plurality of first electrical connection metal portions 180 may be formed in a solder ball attachment and a reflow process, respectively. If necessary, a cutting process may be performed. The printed circuit board 100C in the form of the unit board described above may be formed in the cutting process.

Other descriptions may be substantially the same as those described in the printed circuit boards 100A, 100B and 100C described above and the manufacturing example of the printed circuit board 100A described above, and duplicate descriptions thereof will be omitted.

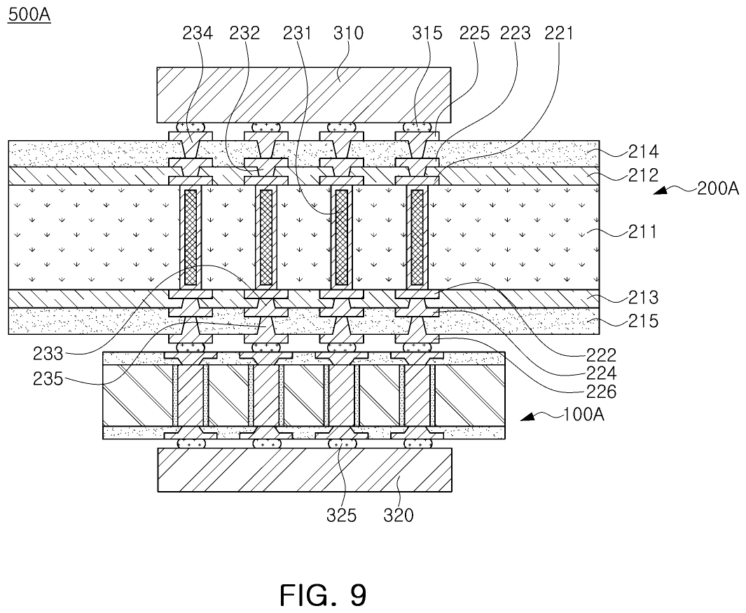

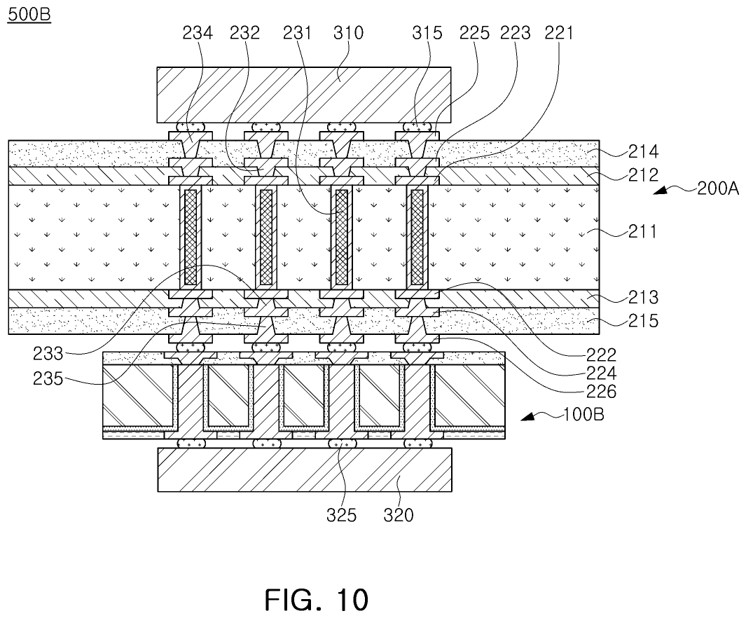

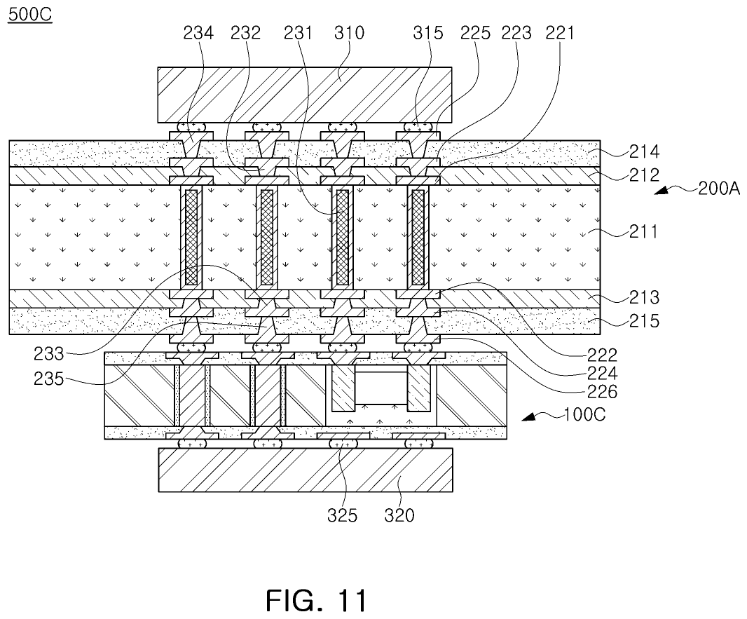

FIGS. 9 to 11 are cross-sectional views schematically illustrating modified examples of the printed circuit boards of FIGS. 3, 5 and 7, respectively.

Referring to the drawings, each of printed circuit boards 500A, 500B and 500C according to modified examples may include a first substrate 200A, a second electronic component 310 mounted on an upper side of the first substrate 200A, MCAI structures 100A, 100B and 100C mounted on a lower side of the first substrate 200A, and a third electronic component 320 mounted on a lower side of the MCAI structures 100A, 100B and 100C. For example, the printed circuit boards 100A, 100B and 100C described above may be mounted on the lower side of the first substrate 200A as the MCAI structures 100A, 100B and 100C, and the third electronic component 320 including a Power Management Integrated Circuit (PMIC) and a Voltage Regulator (VR) may be mounted on the MCAI structures 100A, 100B and 100C. In this case, effects such as volume reduction, structural simplification and current path reduction may be expected. More specifically, as compared to simply forming a pattern inductor on the substrate, the effect of reducing the length of the pattern may be achieved, from which inductor resistance reduction and system efficiency increase may be expected. Additionally, design convenience of the application and size reduction may be expected due to increased capacity. Additionally, the efficiency of mounted components such as PMIC and VR may be increased due to a reduced current path.

Hereinafter, components of printed circuit boards 500A, 500B and 500C according to modified embodiments will be described in more detail with reference to the drawings.

The first substrate 200A may be a multilayer printed circuit board including a plurality of insulating layers 211, 212, 213, 214 and 215, a plurality of interconnection layers 221, 223, 224, 225 and 226, and a plurality of via layers 231, 232, 233, 234 and 235. For example, the plurality of insulating layers 211, 212, 213, 214 and 215 may include a first insulating layer 211 as a core layer, second and third insulating layers 212 and 213 as build-up layers, and fourth and fifth insulating layers 214 and 215 as solder resist layers. Additionally, a plurality of interconnection layers 221, 222, 223, 224 225 and 226 may include first and second interconnection layers 221 and 222 as core interconnection layers, and third to sixth interconnection layers 223, 224, 225, and 226 as build-up interconnection layers. Additionally, the plurality of via layers 231, 232, 233, 234 and 235 may include a first via layer 231 including through-vias and second to fifth via layers 232, 233, 234 and 235 including connection vias, respectively. Meanwhile, the first substrate 200A may a core type multilayer printed circuit board, but may be a coreless type multilayer printed circuit board.

A plurality of insulating layers 211, 212, 213, 214 and 215 may include an inorganic insulating material and/or an organic insulating material. For example, as a non-limiting example, all of the plurality of insulating layers 211, 212, 213, 214 and 215 may include an organic insulating material. Alternatively, the first insulating layer 211 may include an inorganic insulating material, while the second to fifth insulating layers 212, 213, 214 and 215 may include an organic insulating material. However, the present disclosure is not limited thereto. The organic insulating material may include a thermosetting resin such as an epoxy resin, a thermoplastic resin such as polyimide, or an inorganic filler and/or a glass fiber together along with the resin. For example, the organic insulating material may be a Copper Clad Laminate (CCL), PPG, ABF, PID, SR, or the like, but the present disclosure is not limited thereto. The inorganic insulating material may include a glass substrate, a silicon substrate and/or a ceramic substrate. For example, the glass substrate may include glass, and the glass may include, for example, pure silicon dioxide (about 100% SiO₂), soda lime glass, borosilicate glass, and alumino-silicate glass. However, the present disclosure is not limited thereto, and alternative glass materials such as fluorine glass, phosphate glass, chalcogen glass, or the like, may also be used as materials for the glass layer. Additionally, other additives may also be included to form glass having specific physical properties. These additives may include calcium carbonate (e.g., lime) and sodium carbonate (e.g., soda), as well as magnesium, calcium, manganese, aluminum, lead, boron, iron, chromium, potassium, sulfur, and antimony, and carbonates and/or oxides of these elements and other elements. Meanwhile, the glass may be distinguished from glass fibers included in the organic insulating material. Additionally, the silicon substrate may include silicon (Si), and if necessary, the silicon substrate may include an oxide layer formed on silicon (Si). Additionally, the silicon substrate may include a nitride layer formed on the oxide layer. Meanwhile, the oxide layer may include a silicon oxide film, and the nitride layer may include a silicon nitride film, but the present disclosure is not limited thereto. Additionally, the ceramic substrate may include a ceramic, and the ceramic may include, for example, alumina (Al₂O₃), aluminum nitride (AlN), silicon carbide (SiC), and silicon nitride (Si₃N₄), but the present disclosure is not limited thereto.

Each of a plurality of interconnection layers 221, 222, 223, 224, 225 and 226 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. Each of the plurality of interconnection layers 221, 222, 223, 224, 225 and 226 may perform various functions according to design. For example, the plurality of interconnection layers 221, 222, 223, 224, 225 and 226 may include a signal pattern, a power pattern, a ground pattern, or the like. Each of these patterns may have various shapes such as a line, a plane, and a pad. The plurality of interconnection layers 221, 222, 223, 224, 225 and 226 may include a seed metal layer and a plating metal layer formed on the seed metal layer, respectively. The seed metal layer may be an electroless plating layer (or chemical copper) and/or a sputtered layer, and the plating metal layer may be an electrolytic plating layer (or electrolytic copper), but the present disclosure is not limited thereto.

Each of a plurality of via layers 231, 232, 233, 234 and 235 may include a metal. The metal may include copper (Cu), aluminum (Al), silver (Ag), tin (Sn), gold (Au), nickel (Ni), lead (Pb), titanium (Ti), and/or alloys thereof. The metal may include, preferably, copper (Cu), but the present disclosure is not limited thereto. Each of a plurality of via layers 231, 232, 233, 234 and 235 may include a filled via filling a via hole or a through-hole, but may include a conformal via disposed along a wall surface of the via hole or the through-hole. Each of the plurality of via layers 231, 232, 233, 234 and 235 may perform various functions according to design. For example, the plurality of via layers 231, 232, 233, 234 and 235 may include a ground via, a power via, and a signal via. Each of the plurality of via layers 231, 232, 233, 234 and 235 may include an electroless plating layer (or chemical copper) and an electrolytic plating layer (or electrocopper). The plurality of via layers 231, 232, 233, 234 and 235 may include a sputter layer instead of the electroless plating layer (or chemical copper), and may include both the sputter layer and the electroless plating layer. The connection vias of each of the second to fifth via layers 232, 233, 234 and 235 may have a tapered shape in cross-section. Each of the through-vias of the first via layer 231 may have a pillar shape in cross-section, and may have a filling material of an insulating material or a conductive material disposed therein.

The second electronic component 310 may include a semiconductor chip. The semiconductor chip may be an integrated circuit (IC) die in which hundreds to millions of devices are integrated in one chip. The integrated circuit die may be formed based on an active wafer, in which case silicon (Si), germanium (Ge), gallium arsenide (GaAs), or the like may be used as a base material forming each body. Various circuits may be formed in the body. A connection pad may be formed on a front surface of the body, and the connection pad may include a conductive material such as aluminum (Al), copper (Cu), or the like. The semiconductor chip may include: memory chips such as a volatile memory (e.g., DRAM), a non-volatile memory (e.g., ROM), a flash memory and the like; application processor chips such as a central processor (e.g., CPU), a graphics processor (e.g., GPU), a digital signal processor, an encryption processor, a microprocessor, a microcontroller, and the like; and logic chips such as an analog-to-digital converter, an application-specific IC (ASICs), and the like, but the present disclosure is not limited thereto. The second electronic component 310 may be connected to the first substrate 200A through a plurality of second electrical connection metal portions 315. Each of a plurality of second electrical connection metal portions 315 may include a low melting point metal such as tin (Sn), and may include, for example, solder, but the present disclosure is not limited thereto.

The third electronic component 320 may include a PMIC and/or VR. The third electronic component 320 may be connected to MCAI structures 100A, 100B and 100C through the plurality of third electrical connection metal portions 325. Each of a plurality of third electrical connection metal portions 325 may include a low melting point metal such as tin (Sn), and may include, for example, solder, but the present disclosure is not limited thereto.

Other descriptions may be substantially the same as those described in the printed circuit boards 100A, 100B and 100C described above, and duplicate descriptions thereof will be omitted.

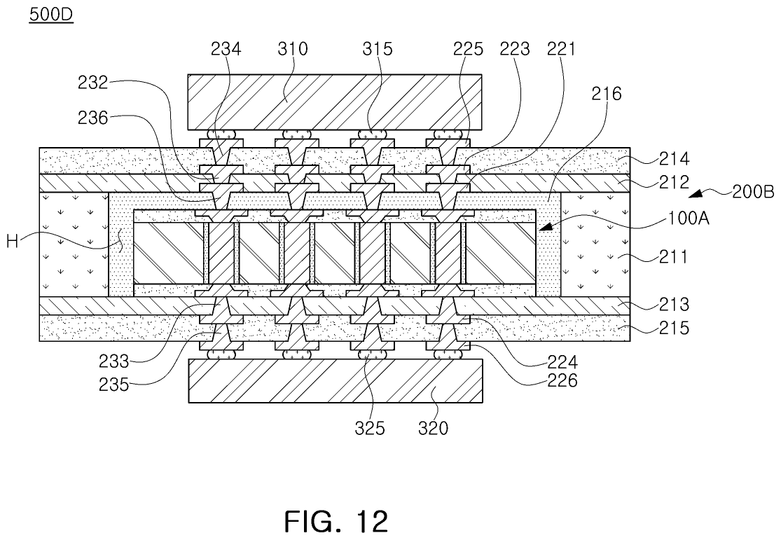

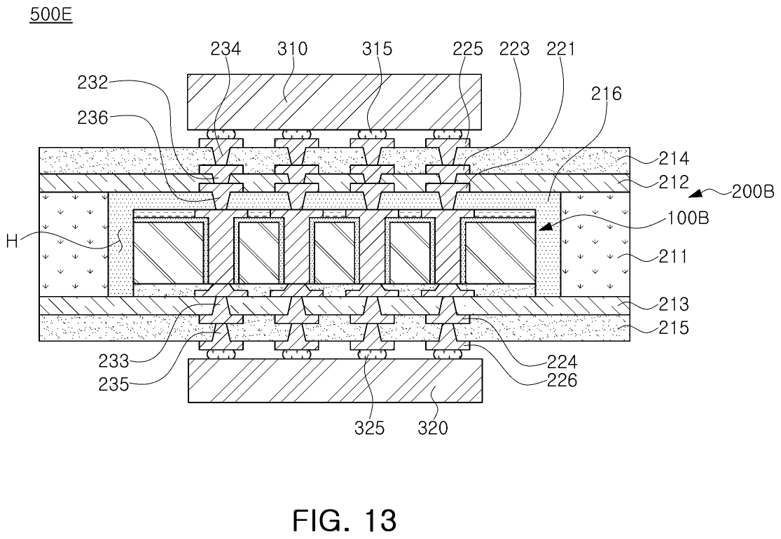

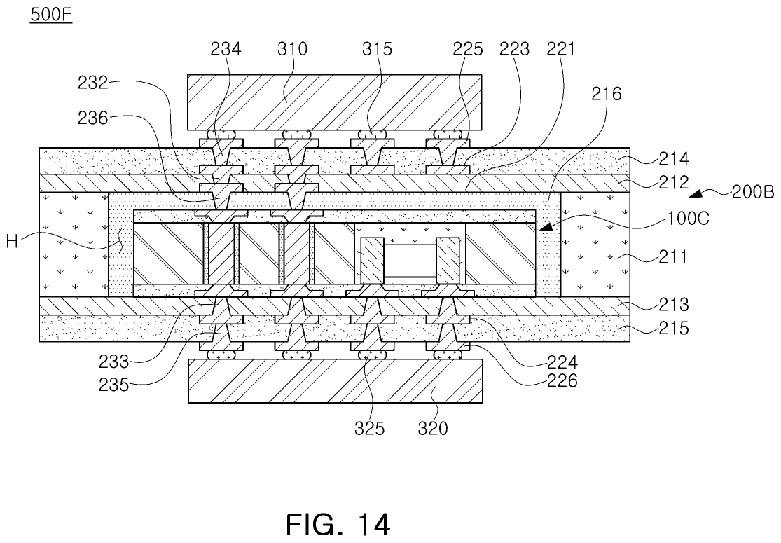

FIGS. 12 to 14 are cross-sectional views schematically illustrating other modified examples of the printed circuit board of FIGS. 3, 5 and 7, respectively.

Referring to the drawings, each of printed circuit boards 500D, 500E and 500F according to another modified embodiment may include a second substrate 200B, a second electronic component 310 mounted on an upper side of the 200B through a plurality of second second substrate electrical connection metal portions 315, MCAI structures 100A, 100B and 100C embedded in the second substrate 200B, and a third electronic component 320 mounted on a lower side of the second substrate 200B through a plurality of third electrical connection metal portions 325. For example, the printed circuit boards 100A, 100B and 100C described above may be embedded in the second substrate 200B as the MCAI structures 100A, 100B and 100C, and the third electronic component 320 including a PMIC and/or a VR or the like may be disposed in lower portions of the MCAI structures 100A, 100B and 100C. Even in this case, effects such as volume reduction, structure simplification, current path reduction, and the like, may be expected.

Hereinafter, elements of the printed circuit boards 500D, 500E and 500F according to another modified embodiment will be described in more detail with reference to the drawings.

The second substrate 200B may be a multilayer printed circuit board including a plurality of insulating layers 211, 212, 213, 214, 215 and 216, a plurality of interconnection layers 221, 223, 224, 225 and 226, and a plurality of via layers 232, 233, 234, 235 and 236. For example, the plurality of insulating layers 211, 212, 213, 214 and 215 may include a first insulating layer 211 as a core layer having a through-portion H in which the MCAI structures 100A, 100B and 100C are disposed, second and third insulating layers 212 and 213 as build-up layers, fourth and fifth insulating layers 214 and 215 as solder resist layers, and a sixth insulating layer 216 as an encapsulant. The sixth insulating layer 216 may include the organic insulating material described above similarly to the second and third insulating layers 212 and 213. The sixth insulating layer 216 may be integrated with the second insulating layer 212 without boundaries. The sixth insulating layer 216 may cover at least portions of the MCAI structures 100A, 100B and 100C, and may fill at least a portion of the through-portion H. Additionally, the plurality of interconnection layers 221, 223, 224, 225 and 226 may include a first interconnection layer 221 as a core interconnection layer and third to sixth interconnection layers 223, 224, 225 and 226 as build-up interconnection layers. Additionally, the plurality of via layers 232, 233, 234, 235 and 236 may include second to sixth via layers 232, 233, 234, 235 and 236 each including connection vias. The sixth via layer 236 may include a connection via having a tapered shape in cross-section, similarly to the second to fifth via layers 232, 233, 234 and 235. The second substrate 200B may be a core type multilayer printed circuit board, but may also be a coreless type multilayer printed circuit board.

Other descriptions may be substantially the same as those described in the printed circuit boards 100A, 100B and 100C described above, and the printed circuit boards 500A, 500B and 500C according to a modified embodiment thereof, and duplicate descriptions thereof will be omitted.

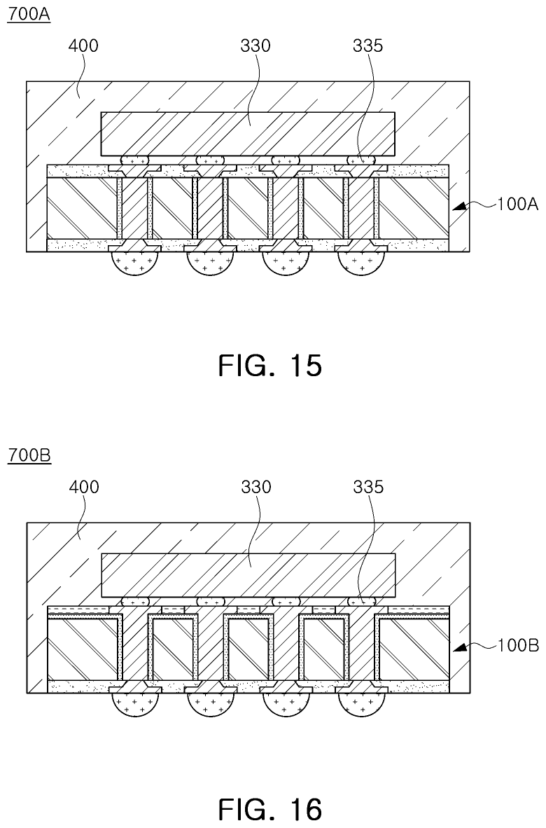

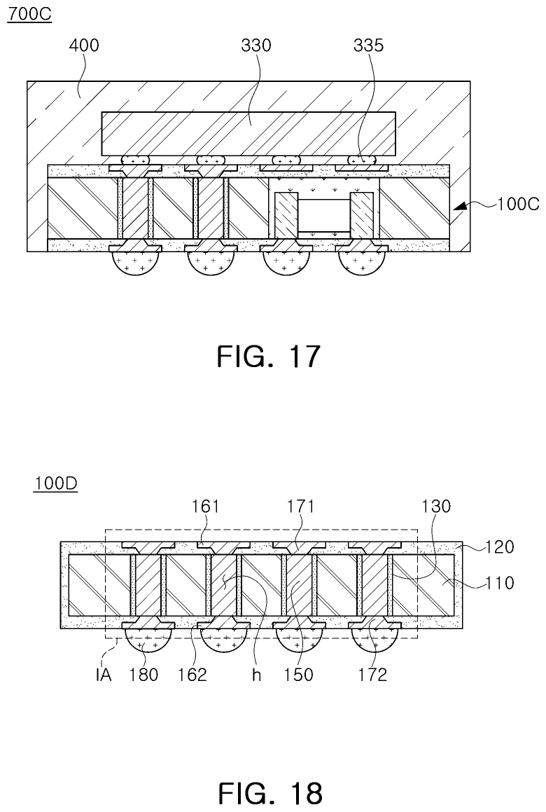

FIGS. 15 to 17 are cross-sectional views schematically illustrating other modified examples of the printed circuit board of FIGS. 3, 5 and 7, respectively.

Referring to the drawings, each of printed circuit boards 700A, 700B and 700C according to another embodiment may include a fourth electronic component 330 mounted on the printed circuit boards 100A, 100B and 100C through a plurality of fourth electrical connection metal portions 335, and a molding material 400 covering at least portions of the printed circuit boards 100A, 100B and 100C and at least a portion of the fourth electronic component 330. For example, in the printed circuit boards 700A, 700B and 700C according to another modified embodiment, the printed circuit boards 100A, 100B and 100C described above may have MCAI structures 100A, 100B and 100C, and the fourth electronic component 330 including a PMIC and/or VR may be mounted on the MCAI structures 100A, 100B and 100C and may be covered with the molding material 400. For example, the printed circuit boards 700A, 700B, and 700C according to another modified embodiment may have a package structure. Even in this case, effects such as volume reduction, structure simplification, current path reduction, and the like, may be expected.

Hereinafter, elements of the printed circuit boards 700A, 700B and 700C according to another modified embodiment will be described in more detail with reference to the drawings.

The fourth electronic component 330 may include the PMIC and/or VR. However, the present disclosure is not limited thereto, and the fourth electronic component 330 may further include other semiconductor chips or chip-type passive components. Each of the plurality of fourth electrical connection metal portions 335 may include a low melting point metal such as tin (Sn), and may include, for example, solder, but the present disclosure is not limited thereto.

The molding material 400 may cover at least a portion of the fourth electronic component 330, and may cover at least portions of upper surfaces of the MCAI structures 100A, 100B and 100C as well as at least portions of side surfaces thereof. The molding material 400 may include a known insulating material such as an epoxy resin. For example, the molding material 400 may include an epoxy molding compound (EMC). However, the present disclosure is not limited thereto, and other types of insulating materials may certainly be used as the molding material 400.

Other descriptions may be substantially the same as those described in the printed circuit boards 100A, 100B and 100C described above, and the printed circuit boards 500A, 500B, 500C, 500D, 500E and 500F according to a modified embodiment thereof, and duplicate descriptions will be omitted.

FIG. 18 is a cross-sectional view schematically illustrating another example of a printed circuit board.

Referring to the drawing, a printed circuit board 100D according to another embodiment may be configured so that the first and second insulating layers 121 and 122 may be integrated with each other to form one insulating layer 120, in which case the insulating layer 120 may cover at least a portion of a side surface of the magnetic layer 110. For example, the insulating layer 120 may surround the magnetic layer 110 so that the side surface of the magnetic layer 110 is not exposed. Meanwhile, the printed circuit board 100D according to another embodiment may include an MCAI structure, and more specifically, the printed circuit board 100D may include an inductor array IA including a magnetic layer 110, an insulating layer 120, a plurality of insulating films 130, a plurality of through-vias 150, a plurality of second pads 161 and 162, and a plurality of first and second connection vias 171 and 172.

Other descriptions may be substantially the same as those described in the printed circuit board 100A according to an example embodiment, and duplicate descriptions thereof will be omitted. Meanwhile, the printed circuit board 100D according to another embodiment may be applied to each structure described in the printed circuit board 500A according to the modified embodiment described above and the printed circuit board 700A according to another embodiment, instead of the printed circuit board 100A according to an example embodiment described above, and duplicate descriptions thereof will be omitted.

In the present disclosure, the expression ‘covering’ may include a case of covering at least a portion as well as a case of covering the whole, and may also include a case of covering not only directly but also indirectly. Furthermore, the expression ‘filling’ may include not only a case of completely filling but also a case of partially filling, and may also include a case of approximately filling. For example, this may include a case in which some pores or voids exist. Additionally, the expression ‘surrounding’ may include not only a case of completely surrounding but also a case of partially surrounding and a case of approximately surrounding. Additionally, exposing may include partial exposing as well as a case of complete exposing, and exposure may refer to exposure from embedding a corresponding component. For example, exposing a pad by an opening may be exposing the pad from a resist layer, and a surface treatment layer or the like may be further disposed on the exposed pad.

In the present disclosure, being disposed in a through-portion or a through-hole may include not only cases in which an object is disposed completely in the through-portion or the through-hole, but also cases in which the object partially protrudes therefrom upwardly or downwardly in cross-section. For example, when the object is disposed in the through-portion or the through-hole in plan view, this may be determined in a broader sense.

In the present disclosure, determination may be performed by including process errors, positional deviations, errors at the time of measurement, which may occur substantially in a manufacturing process. In one or more aspects, the term “being substantially the same” (“about,” “approximately,” etc.) may indicate “being the same” or being within an industry-accepted tolerance, due to a process error or a measurement error recognizable by one of ordinary skill in the art provide, for the corresponding term and/or relativity between items, such as a tolerance of ±18, ±5%, or ±10% of the actual value stated, and other suitable tolerances. For example, being substantially vertical may include not only being completely vertical but also being approximately vertical. Furthermore, being substantially coplanar may include not only a case in which elements are completely on the same plane, but also a case in which the elements are approximately on the same plane.

In the present disclosure, the same insulating material may denote not only the same insulating material but also the same type of insulating material. Accordingly, the compositions of the insulating materials may be substantially the same, but specific composition ratios thereof may be slightly different.

In the present disclosure, the meaning on the cross-section may refer to a cross-sectional shape when an object is cut vertically, or a cross-sectional shape when the object is viewed in a side-view. Furthermore, the meaning on a plane may refer to a planar shape when the object is horizontally cut, or a planar shape when the object is viewed in a top-view or a bottom-view.

In the present disclosure, for convenience, a lower side, a lower portion, and a lower surface are used to refer to a downward direction with respect to a cross-section of a drawing, and an upper side, an upper portion, and an upper surface are used to refer to an opposite direction thereof. However, this is a definition of direction for the convenience of explanation, and the scope of the claim is not specifically limited by the description of this direction, and the concept of upper/lower may be changed at any time.

In the present disclosure, a meaning of being connected is a concept including not only directly connected but also indirectly connected through an adhesive layer or the like. Furthermore, a meaning of electrically connected is a concept including both physically connected and not connected. In addition, expressions such as first and second are used to distinguish one component from another, and do not limit the order and/or importance of the components. In some cases, a first component may be referred to as a second component without departing from the scope of rights, or similarly, the second component may be referred to as the first component.

In the present disclosure, a thickness, a width, a length, a depth, a line width, a gap, a pitch, a separation distance, surface roughness, and the like, may be measured using a scanning microscope, an optical microscope, or the like, based on a cross-section of a printed circuit board that has been polished or cut, respectively. The cut cross-section may be a vertical cross-section or a horizontal cross-section, and each value may be measured based on a required cut cross-section. For example, a width of an upper portion and/or a lower portion of a via may be measured on a cross-section that has been cut along a central axis of the via. In this case, when the value is not constant, the value may be determined as an average value of values measured at five arbitrary points.

The expression ‘example embodiment used in the present disclosure’ does not mean the same embodiment, and is provided to explain different unique characteristics. However, the example embodiments presented above do not preclude being implemented in combination with features of other example embodiments. For example, even if matters described d in a particular example embodiment are not described in other example embodiments, they may be understood as explanations related to other example embodiments unless there is an explanation contrary to or contradictory to matters in other example embodiments.

The terms used in the present disclosure are used only to describe an example embodiment and are not intended to limit the present disclosure. In this case, singular expressions include plural expressions unless they are clearly meant differently in the context.

What is claimed is:

1. A printed circuit board, comprising:
a magnetic layer;
a plurality of through-vias respectively penetrating through the magnetic layer;
a plurality of first pads disposed on upper surfaces of the plurality of through-vias, respectively;
a plurality of second pads disposed on lower surfaces of the plurality of through-vias, respectively;
a first insulating layer covering at least portions of the plurality of first pads;
a second insulating layer covering at least portions of the plurality of second pads,
wherein at least a portion of a side surface of the magnetic layer is substantially coplanar with at least a portion of one or more of a side surface of the first insulating layer and a side surface of the second insulating layer.

2. The printed circuit board according to claim 1, further comprising:
a plurality of insulating films respectively disposed between the plurality of through-vias and the magnetic layer, and respectively surrounding side surfaces of the plurality of through-vias.

3. The printed circuit board according to claim 2,
wherein the plurality of insulating films include an inorganic insulating material, and
the inorganic insulating material includes one or more of Al₂O₃, TiO₂, ZnO, ZnO₂, ZrO₂, SnO, SnO₂, HfO₂ and SiO₂.

4. The printed circuit board according to claim 2,
wherein in cross-section, a width of one of the plurality of insulating films is 2 μm or less based on a direction, perpendicular to the side surfaces of one of the plurality of through-vias.

5. The printed circuit board according to claim 2, further comprising:
a plurality of first connection vias respectively penetrating through the first insulating layer and respectively connecting the plurality of first pads and the plurality of through-vias to each other; and
a plurality of second connection vias respectively penetrating through the second insulating layer and respectively connecting the plurality of second pads and the plurality of through-vias to each other.

6. The printed circuit board according to claim 5,
wherein a lower surface of the magnetic layer, lower surfaces of each of the plurality of insulating films, and the lower surfaces of each of the plurality of through-vias are substantially coplanar with each other.

7. The printed circuit board according to claim 6,
wherein an upper surface of the magnetic layer, upper surfaces of each of the plurality of insulating films, and the upper surfaces of each of the plurality of through-vias are substantially coplanar with each other.

8. The printed circuit board according to claim 5,
wherein the first and second insulating layers include substantially the same insulating material.

9. The printed circuit board according to claim 5, the first and second insulating layers have substantially the same thickness.

10. The printed circuit board according to claim 2, further comprising:
a plurality of second connection vias respectively penetrating through the second insulating layer and respectively connecting the plurality of second pads and the plurality of through-vias to each other,
wherein the plurality of insulating films extend onto an upper surface of the magnetic layer, and
at least portions of extended portions of the plurality of insulating films are disposed between the first insulating layer and the magnetic layer, and
the plurality of first pads are directly connected to the plurality of through-vias, respectively.

11. The printed circuit board according to claim 10,
wherein an upper surface of each of the plurality of through-vias protrudes onto the upper surface of the magnetic layer, and
a lower surface of the magnetic layer, lower surfaces of each of the plurality of insulating films, and the lower surfaces of each of the plurality of through-vias are substantially coplanar with each other.

12. The printed circuit board according to claim 10,
wherein the first and second insulating layers include different insulating materials.

13. The printed circuit board according to claim 10,
wherein the second insulating layer has a thickness thicker than the first insulating layer.

14. The printed circuit board according to claim 1, further comprising:
a first electronic component, at least a portion of which is disposed in a cavity penetrating through at least a portion of the magnetic layer; and
an encapsulant covering at least a portion of the first electronic component and disposed in at least a portion of the cavity.

15. The printed circuit board according to claim 1, further comprising:
a plurality of electrical connection metal portions respectively disposed on a lower side of the second insulating layer and respectively connected to the plurality of second pads.

16. The printed circuit board according to claim 1, further comprising:
a substrate including a plurality of insulating layers, a plurality of interconnection layers, and a plurality of via layers;
a second electronic component mounted on an upper side of the substrate;
a Magnetic Core Array Inductor (MCAI) structure mounted on a lower side of the substrate; and
a third electronic component mounted on a lower side of the MCAI structure,
wherein the MCAI structure further includes the magnetic layer, the plurality of through-vias, the plurality of first and second pads, and the first and second insulating layers.

17. The printed circuit board according to claim 1, further comprising:
a substrate including a plurality of insulating layers, a plurality of interconnection layers, and a plurality of via layers;
a second electronic component mounted on an upper side of the substrate;
a Magnetic Core Array structure Inductor (MCAI) embedded in the substrate; and
a third electronic component mounted on a lower side of the substrate,
wherein the MCAI structure includes the magnetic layer, the plurality of through-vias, the plurality of first and second pads, and the first and second insulating layers.

18. The printed circuit board according to claim 1, further comprising:
a Magnetic Core Array Inductor (MCAI) structure;
a fourth electronic component mounted on an upper side of the MCAI structure; and
a molding material covering at least portions of each of the MCAI structure and the fourth electronic component,
wherein the MCAI structure includes the magnetic layer, the plurality of through-vias, the plurality of first and second pads, and the first and second insulating layers.

19. A printed circuit board, comprising:
a magnetic layer having a plurality of through-holes;
a plurality of insulating films respectively disposed on wall surfaces of the plurality of through-holes;
a plurality of metal pillars respectively disposed on the plurality of insulating films and disposed in at least portions of the plurality of through-holes;
an insulating layer covering one or more of an upper surface and a lower surface of the magnetic layer; and
a plurality of metal patterns each of which is at least partially embedded in the insulating layer and is respectively connected to one or more of upper surfaces and lower surfaces of the plurality of metal pillars,
wherein at least a portion of a lower surface of the magnetic layer is substantially coplanar with at least a portion of a lower surface of at least one of the plurality of metal pillars.

20. The printed circuit board according to claim 19, wherein the insulating layer extending between the upper surface and the lower surface of the magnetic layer to cover a side surface of the magnetic layer.
